(19) United States
(12) Patent Application Publication
(10) Pub. No.: US 2009/0301538 A1
(43) Pub. Date: Dec. 10, 2009

(54) Thermoelectric module

(76) Inventor: Joel Lindstrom, Bozeman, MT (US)

Correspondence Address: DEVINE, MILLIMET & BRANCH, P.A., 111 AMHERST STREET, BOX 719, MANCHESTER, NH, 03105, US

(21) Appl. No.: 12/456,323

(22) Filed: Jun. 15, 2009

Related U.S. Application Data
(63) Continuation-in-part of application No. 12/002,154, filed on Dec. 14, 2007.
(60) Provisional application No. 60/874,788, filed on Dec. 14, 2006.

(51) Int. Cl. H01L 35/34; H01L 37/00

(52) U.S. Cl. 136/201; 136/200

(57) ABSTRACT

A novel thermoelectric module in which the thermoelectric elements are stacked together with thermal and electrical conductors integrated in the stack to perform the dual functions of conducting both heat and electricity.

### CROSS-REFERENCE TO RELATED APPLICATIONS

The present application is a continuation-in-part of U.S. patent application Ser. No. 12/002,154 filed Dec. 14, 2007, which is incorporated herein by reference and which claims the benefit of provisional patent application Ser. No. 60/874,788, filed Dec. 14, 2006, which is also incorporated herein by reference.

### TECHNICAL FIELD

The present invention relates to thermoelectric (TE) technology used for the production of electricity as well as for heating or cooling. Specifically, it relates to a geometrical structure of a TE module and a method of producing such structure.

### BACKGROUND OF THE INVENTION

TE technology is based on the concept that a temperature differential may be converted into electricity and vice versa. Namely, the Seebeck effect is the conversion of a temperature differential directly into electricity, and the Peltier effect is the production of a temperature differential from a difference in electric potential.

TE modules hold great promise for widespread use due to their solid state structure, silent operation, high reliability and long service life. TE modules used for power generation can produce electricity from virtually any source of heat, which could enable many energy conversion processes to increase efficiency, reduce pollutant emissions and lower costs. TE modules used for heating or cooling can achieve very sensitive temperature control, and TE modules used for cooling do not require volatile working fluids.

The conventional bulk die design for TE modules in the prior art is shown in FIGS. 1 and 2. FIG. 1 shows the exterior of such a TE module 10. FIG. 2 shows interior of TE module 10, including the thermoelectric elements 20, the electrical conductors 22 affixed on the ends of the thermoelectric elements 20, and the electrically insulating substrates 24. This design suffers:
1. Need for additional heat transfer equipment when gas or liquid mediums are used as the heat source and or heat sink. This need also results in large thermal contact resistances across mating surfaces between heat exchanger and TE module (10-15° C. loss on each side is typical). Further, this need also creates an excessive thermal path length, adds considerable mass to the overall system, and is difficult to integrate with existing heat exchange processes,
2. Long electric current path and resulting high Ohmic loss
3. Difficult and expensive component manufacture and module assembly,
4. Limited module size due to excessive thermal stress, and
5. Limitations on soldered designs to temperatures below 225° C.

Improvements in TE material production methods resulted in the conventional thin film design, as shown in FIG. 3. This TE module 30 comprises thin film thermoelectric elements 32, electrical conductors 34 on the tops and bottoms of the thermoelectric elements 32, and electrically insulating substrates 36. This design can make use of new thermoelectric material and has a much shorter electric current path than the conventional bulk die design, resulting in a reduction in Ohmic loss. However, the thinner thermoelectric elements result in increased difficulty in maintaining a sufficient temperature gradient across the thermoelectric elements. In addition, the conventional thin film design also suffers from the other disadvantages listed for the conventional bulk die design.

As a result, another thin film design has been developed, as shown in FIG. 4. This TE module 40 comprises thin film thermoelectric elements 42, electrical conductors 44 affixed to the ends of the thermoelectric elements 42, and electrically insulating substrates 46. This design has the advantages of the conventional thin film design and can withstand large temperature gradients without generating excessive thermal stress. It also has simple component manufacture and assembly. However, it still suffers from the need for additional heat transfer equipment to transfer effectively heat to and or from gas or liquid mediums via convection. It also uses thermoelectric material inefficiently and has significant limitations on stack length.

Yet another design for a TE module is described in U.S. patent application Ser. No. 12/002,154 (the “'154 application”), which is incorporated herein by reference. As is described in more detail below, the '154 application describes a TE module geometry in which the thermoelectric elements are stacked together and thermal and electrical conductors are interleaved between the thermoelectric elements to perform the dual functions of conducting both heat and electricity. The present invention is an improvement on the TE module of the '154 application and on the method of producing it.

### SUMMARY

The present invention comprises a novel TE module geometry and a method of producing such geometry. In this TE module geometry, the thermoelectric elements are stacked together and thermal and electrical conductors are interleaved between the thermoelectric elements to perform the dual functions of conducting both heat and electricity.

### BRIEF DESCRIPTION OF THE DRAWINGS

These and other features and advantages of the present invention will be better understood by reading the following detailed description, taken together with the drawings wherein a preferred embodiment is shown as follows:

FIG. 1 shows the exterior of a bulk design TE module of the prior art;

FIG. 2 shows a schematic diagram of the interior of a bulk design TE module of the prior art;

FIG. 3 shows a schematic diagram of a first thin film TE module of the prior art;

FIG. 4 shows a schematic diagram of a second thin film TE module of the prior art;

FIG. 5 shows a schematic diagram of the TE module of the '154 application; and

FIG. 6 shows a schematic diagram of a preferred embodiment of the TE module of the present invention.

### DETAILED DESCRIPTION OF THE PREFERRED EMBODIMENTS

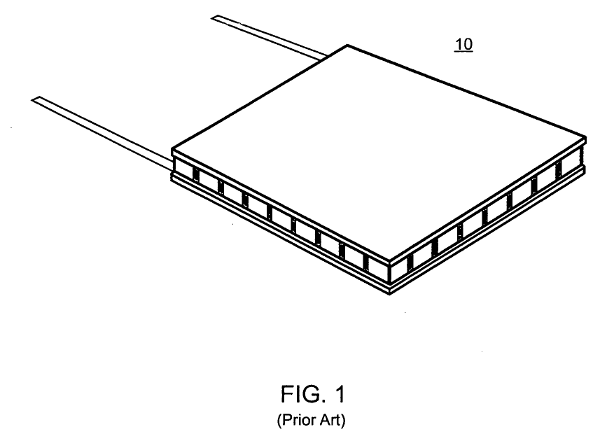

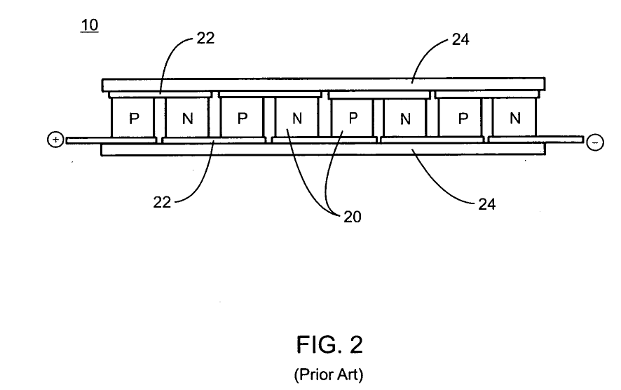

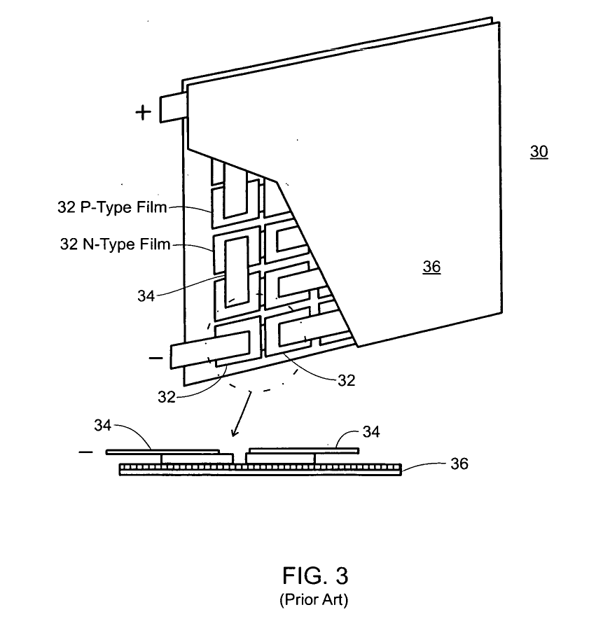

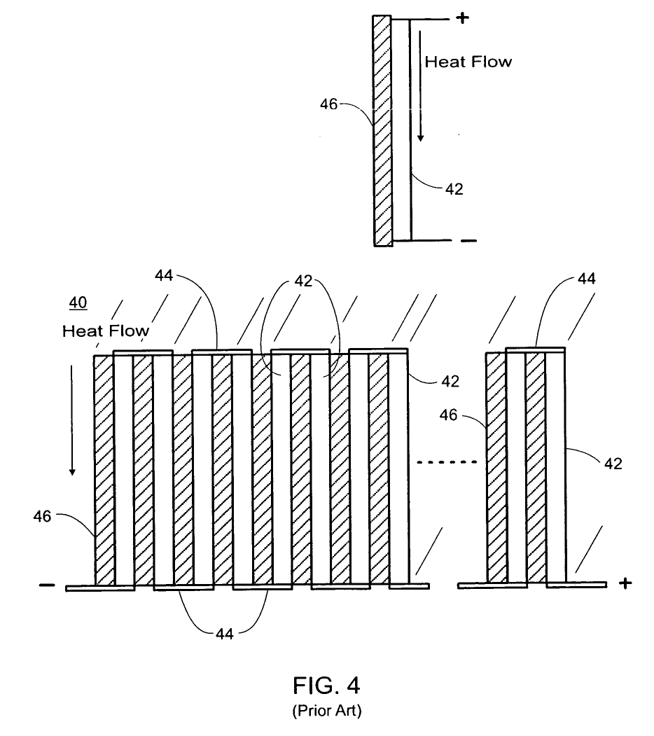

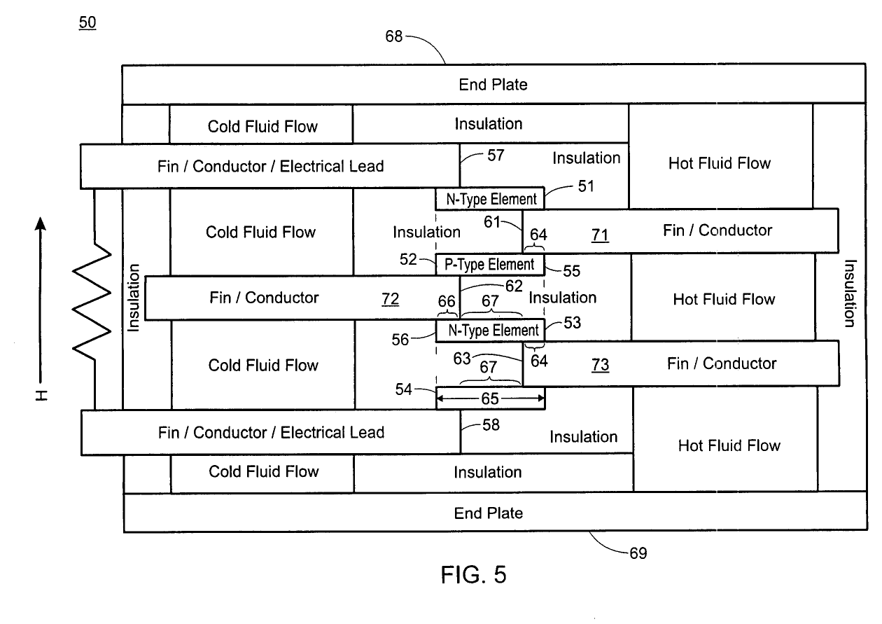

The TE module geometry of the '154 application is shown in FIG. 5, which is not of precise geometric scale and does not contain a realistic number of thermoelectric elements for an actual TE module. In this TE module structure, thin thermoelectric element strips are stacked together, with thermal and electrical conductors integrated within the stack. Namely, thermal and electrical conductors are interleaved in the spaces between the thermoelectric elements to perform the dual function of conducting heat and electricity. In the prior art, shown in FIGS. 1-4, electrical conductors were affixed only to the ends of the thermoelectric elements and did not perform any consequential role in transferring heat directly to or from the heat sink and heat source, respectively. In addition, the thermal and electrical conductors of this geometry can be extended outside of the stack to perform the function of accepting or rejecting heat to or from a gas or liquid medium via convection.

In the geometry shown in FIG. 5, a TE module 50 has a first thermoelectric element 51, a second thermoelectric element 52, a third thermoelectric element 53 and a fourth thermoelectric element 54 arranged in a stack. The stack has a first side 55 and a second side 56 opposite the first side 55. A top electric lead 57 is attached to the top of the first thermoelectric element 51 and a bottom electric lead 58 is attached to the bottom of the fourth thermoelectric element 54. A top end plate 68 is placed on top of the top electric lead 57 and a bottom end plate 69 is placed on the bottom of the bottom electric lead 58.

There are first 61, second 62 and third 63 thermal and electric conductors. The first 61 and the third 63 thermal and electrical conductors are interleaved between the first thermoelectric element 51 and the second thermoelectric element 52 and between the third 53 and fourth 54 thermoelectric elements, respectively. The first thermal and electrical conductor 61 and the third thermal and electrical conductor 63 extend a first specified distance 64 into the stack from the first side 55, which distance 64 is less than the distance 65 from the first side 55 of the stack to the second side 56 of the stack. The second thermal and electrical conductor 62 is interleaved between the second thermoelectric element 52 and the third thermoelectric element 53. The second thermal and electrical conductor 62 extends a second specified distance 66 into the stack from the second side 56, which distance 66 is less than the distance 65 from the second side 56 of the stack to the first side 55 of the stack.

In the present invention, thermoelectric elements are again stacked together and thermal and electrical conductors are again interleaved in the spaces between the thermoelectric elements to perform the dual function of conducting heat and electricity. In addition, the thermal and electrical conductors of this geometry can also be extended outside of the stack to perform the function of accepting or rejecting heat to or from a gas or liquid medium via convection. In the present invention, however, the thermal and electrical conductors extend farther into, and in some cases through, the stack.

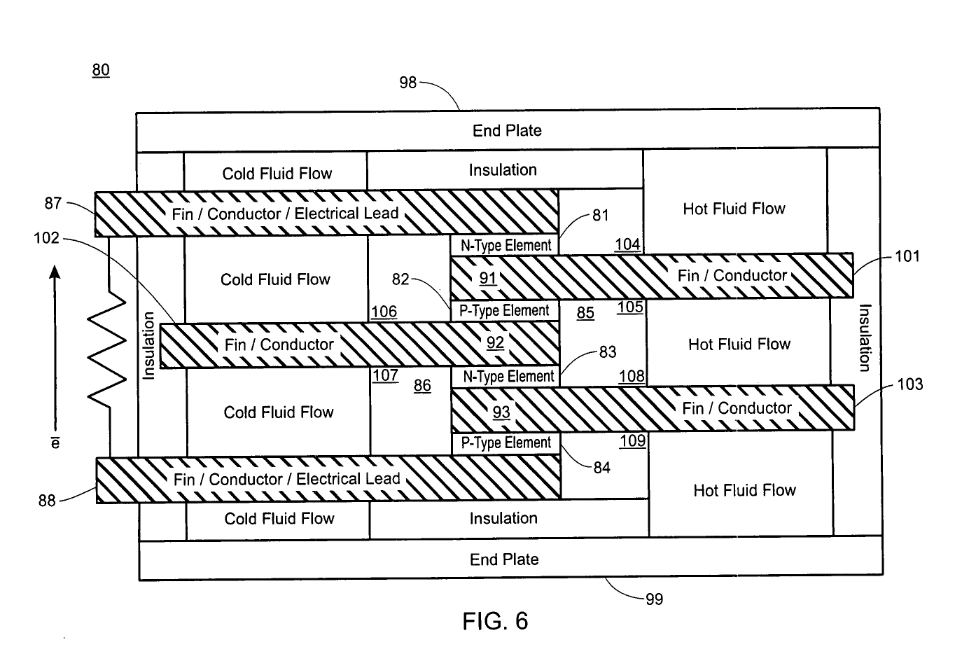

In the preferred embodiment shown in FIG. 6, a TE module 80 has a first thermoelectric element 81, a second thermoelectric element 82, a third thermoelectric element 83 and a fourth thermoelectric element 84 arranged in a stack. The stack has a first side 85 and a second side 86 opposite the first side 85. A top electric lead 87 is attached to the top of the first thermoelectric element 81 and a bottom electric lead 88 is attached to the bottom of the fourth thermoelectric element 84. A top end plate 98 is placed on top of the top electric lead 87 and a bottom end plate 99 is placed on the bottom of the bottom electric lead 88.

There are first 91, second 92 and third 93 thermal and electric conductors. The first 91 and the third 93 thermal and electrical conductors are interleaved between the first thermoelectric element 81 and the second thermoelectric element 82 and between the third 83 and fourth 84 thermoelectric elements, respectively. The first thermal and electrical conductor 91 and the third thermal and electrical conductor 93 extend into the stack from the first side 85 of the stack to the second side 86 of the stack. The second thermal and electrical conductor 92 is interleaved between the second thermoelectric element 82 and the third thermoelectric element 83. The second thermal and electrical conductor 92 extends into the stack from the second side 86 of the stack to the first side 85 of the stack.

The temperature differential spans a thermoelectric element from the bottom of a thermal and electrical conductor on the top of the thermoelectric element to the top of a thermal and electrical conductor on the bottom of the thermoelectric element. For example, the temperature differential spans thermoelectric element 82 from the bottom 105 of thermal and electrical conductor 91 to the top 106 of thermal and electrical conductor 92.

In another preferred embodiment, the thermal and electrical conductors 91, 93 extend into the stack from the first side 85 to, and through, the second side 86. Thermal and electrical conductor 92 extends into the stack from the second side 86 to, and through, the first side 85.

In the embodiment shown in FIG. 6, extensions 101, 102, 103 of the integrated thermal and electrical conductors 91, 92, 93 are extended out of the stack to perform the function of convective heat transfer fins. They would be subject to electrical charge. However, there are a number of means for producing electrical insulation of extensions 101, 102, 103 of the thermal and electrical conductors extending out of the stack. For example, a bimetallic fin, an insulative coating or a similar method known to those skilled in the art may be used to negate the potential for electrical short between the extensions of the conductors. FIG. 6 also illustrates an embodiment of the present invention where an insulating shroud affords mechanical structure for the electrically charged fins, as well as ducting for the hot and cold gases that flow through the conductor arrays.

If the TE module is to collect and reject heat from gas and or liquid mediums, then extensions of the thermal and electrical conductors would preferably be operated in counterflow fashion, where the hot fluid would flow into the plane of FIG. 6 and the cold fluid would flow out of the plane of FIG. 6. In other embodiments, the TE module of the present invention may also be used in parallel flow configurations. The thermal and electrical conductors 91, 92, 93 do not have to extend outside of the stack and may be truncated to provide a flat surface for exchanging heat via conduction or radiation. If they are not truncated, they need not be straight, as the extensions 101, 102, 103 could be formed into high performance wavy or interrupted heat transfer surfaces using conventional plate-stamping techniques.

Copper and aluminum alloys with high thermal and electrical conductivity are a desirable thermal and electrical conductor material for low to mid temperature operation, and 400 series stainless steels or Inconel materials may be used for higher temperature operation.

Another desirable property of the geometry of the present embodiment is the relatively insignificant thermal stresses that are exhibited during operation as a result of the non-monolithic structure of the stack. To ensure sound thermal and electrical continuity, the stack can be compressed between the top end plate 98 and the bottom end plate 99 using mechanical forces applied by compression means such as screw, spring, compressed gas or other conventional compression techniques known to those skilled in the art. Sheet structures comprised of ceramic, acrylic, aramid and other high temperature materials are desirable insulators for the present invention used in the power generation mode given their additional characteristics of low thermal conductivity, low electrical conductivity, superior compliance and low cost. The ability of these insulation materials to exhibit a high level of compliance permits the conductor materials to undergo large changes in size due to thermal expansion. The permitting of large amounts of thermal expansion enables the use of high temperature as well as very high temperature differentials relative to prior art TE technology. For similar reasons, plastics such as polyimide are a desirable insulation material for the present invention used in the cooling mode, namely due to their low thermal conductivity, low electrical conductivity, very low elastic modulus and low cost. It should be noted that there are numerous insulation materials that could be used to fabricate an embodiment of the present invention, for both power generation and heat pumping modes. Another desirable property of the TE module of the present invention is its simplicity and therefore low cost of manufacture. It is also well suited to modularity.

It is noted that virtually any type of thermoelectric material may be used within the TE module of the present invention for optimal heating, cooling or power generation performance. It should also be reiterated that this concept is highly amenable to power generation, namely in a power plant or industrial process where it could significantly enhance existing heat exchange processes. Namely, intercooling, recuperation or even condenser processes may be enhanced with the present invention, resulting in increased efficiency, reduced pollutant emission, reduced cooling system size and water use (if applicable). For electricity generation in transport vehicles it could enable the long sought “more electric” vehicle concepts, in addition to increasing efficiency and reducing pollutant emission. For remote or distributed power applications it could be used to produce electricity from the combustion effluent of fossil fuels or from heat provided by an advanced solar energy collection system. Conversely, the geometrical structure of the present invention could also be used for providing silent, reliable, long lasting and precise temperature control for a wide array of stationary and mobile heat pumping applications.

While the principles of the invention have been described herein, it is to be understood by those skilled in the art that this description is made only by way of example and not as a limitation as to the scope of the invention. Other embodiments are contemplated within the scope of the present invention in addition to the exemplary embodiments shown and described herein. Modifications and substitutions by one of ordinary skill in the art are considered to be within the scope of the present invention.

What is claimed is:

1. A thermoelectric module comprising,
a first thermoelectric element, a second thermoelectric element and a third thermoelectric element arranged in a stack with a first side and a second side opposite the first side,
a first thermal and electrical conductor interleaved between the first thermoelectric element and the second thermoelectric element so that it extends into the stack from the first side to the second side, and
a second thermal and electrical conductor interleaved between the second thermoelectric element and the third thermoelectric element so that it extends into the stack from the second side to the first side.

2. The thermoelectric module of claim 1 wherein a thermal and electrical conductor does not extend outwardly from the stack.

3. The thermoelectric module of claim 1 wherein an extension of a thermal and electrical conductor extends outwardly from the stack.

4. The thermoelectric module of claim 3 wherein a means for producing electrical insulation electrically insulates the extension of a thermal and electrical conductor extending outwardly from the stack.

5. The thermoelectric module of claim 1 further comprising a top end plate above the first thermoelectric element, a bottom end plate below the third thermoelectric element, and a means for compressing the stack of thermoelectric elements and interleaved thermal and electrical conductors between the end plates.

6. A thermoelectric module comprising,
a first thermoelectric element, a second thermoelectric element and a third thermoelectric element arranged in a stack with a first side and a second side opposite the first side,
a first thermal and electrical conductor interleaved between the first thermoelectric element and the second thermoelectric element so that it extends into the stack from the first side through the second side, and
a second thermal and electrical conductor interleaved between the second thermoelectric element and the third thermoelectric element so that it extends into the stack from the second side through the first side.

7. A thermoelectric module, comprising,
multiple thermoelectric elements arranged in a stack, and
multiple thermal and electric conductors interleaved in the stack.

8. A method of producing a thermoelectric module comprising,
arranging a first thermoelectric element, a second thermoelectric element and a third thermoelectric element in a stack with a first side and a second side opposite the first side,
interleaving a first thermal and electrical conductor between the first thermoelectric element and the second thermoelectric element so that it extends into the stack from the first side to the second side, and
interleaving a second thermal and electrical conductor between the second thermoelectric element and the third thermoelectric element so that it extends into the stack from the second side to the first side.

9. The method of claim 8 further comprising truncating a thermal and electrical conductor so that it does not extend outwardly from the stack.

10. The method of claim 8 further comprising extending an extension of thermal and electrical conductor outwardly from the stack.

11. The method of claim 10 further comprising electrically insulating the extension of the thermal and electrical conductor extending outwardly from the stack.

12. The method of claim 8 further comprising compressing the stack between a top end plate above the first thermoelectric element and a bottom end plate below the third thermoelectric element.

13. A method of producing a thermoelectric module comprising,
arranging a first thermoelectric element, a second thermoelectric element and a third thermoelectric element in a stack with a first side and a second side opposite the first side,
interleaving a first thermal and electrical conductor between the first thermoelectric element and the second thermoelectric element so that it extends into the stack from the first side through the second side, and
interleaving a second thermal and electrical conductor between the second thermoelectric element and the third thermoelectric element so that it extends into the stack from the second side through the first side.

14. A method of producing a thermoelectric module, comprising,
arranging a stack of multiple thermoelectric elements, and
interleaving multiple thermal and electric conductors in the stack.
